(19) United States
(12) Patent Application Publication
(10) Pub. No.: US 2026/0096109 A1
(43) Pub. Date: Apr. 2, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chung-Sung Chiang, Kaohsiung City (TW); Chun-Hsien Lin, Tainan City (TW); I-Ming Tseng, Kaohsiung City (TW); Yu-Chun Chen, Kaohsiung City (TW); Yi-An Shih, Changhua County (TW)

(73) Assignee: UNITED MICROELECTRONICS CORP., Hsin-Chu City (TW)

(21) Appl. No.: 18/931,078

(22) Filed: Oct. 30, 2024

(30) Foreign Application Priority Data
Sep. 27, 2024 (TW) 113136955

(51) Int. Cl. H01L 23/48

(52) U.S. Cl. CPC H10D 1/20; H10W 20/20

(57) ABSTRACT

A semiconductor device includes a first wafer and a second wafer. The first wafer includes a first substrate and a first inductance layer. The first inductance layer includes a first metal line and a first interconnect structure. The first metal line is disposed on the first substrate, and the first interconnect structure is electrically connected with the first metal line. The second wafer includes a second substrate and a second inductance layer. The second inductance layer includes a second metal line and a second interconnect structure. The second metal line is disposed on the second substrate, and the second interconnect structure is electrically connected with the second metal line. The second interconnect structure is bonded with the first interconnect structure, so that the first inductance layer and the second inductance layer together form an inductance element.

### BACKGROUND OF THE INVENTION

### 1. Field of the Invention

The present disclosure relates to the field of semiconductor devices, and more particularly, to a semiconductor device includes an inductance element and a method for fabricating the same.

### 2. Description of the Prior Art

In the fifth generation mobile networks (5G) system, inductance elements are often applied in high-frequency circuits to filter frequencies and control the signal transmissions based on the inductance values thereof. The inductance element has the ability to block specific frequencies or allow specific frequencies to pass through. For example, an inductance element with a higher inductance value allows low-frequency signals to pass through while blocking high-frequency signals. Conversely, an inductance element with a lower inductance value allows high-frequency signals to pass through while blocking low-frequency signals. This characteristic of the inductance element makes it an important component in the filters and matching circuits, which can transmit or block specific signals within a specific frequency range.

The quality factor (Q factor) and the inductance value of the inductance element are the main parameters used to measure the performance of the inductance element. However, the existing inductance elements with higher quality factors and inductance values often require larger areas and/or volumes, which is not beneficial to the current trend of miniaturization of semiconductor devices. Therefore, how to maintain or improve the performance of the inductance element while reducing the area and/or volume of the inductance element has become one of the goals of the relevant industry.

### SUMMARY OF THE INVENTION

According to one aspect of the present disclosure, a semiconductor device includes a first wafer and a second wafer. The first wafer includes a first substrate and a first inductance layer. The first inductance layer includes a first metal line and a first interconnect structure. The first metal line is disposed on the first substrate, and the first interconnect structure is electrically connected with the first metal line. The second wafer includes a second substrate and a second inductance layer. The second inductance layer includes a second metal line and a second interconnect structure. The second metal line is disposed on the second substrate, and the second interconnect structure is electrically connected with the second metal line. The second interconnect structure is bonded with the first interconnect structure, so that the first inductance layer and the second inductance layer together form an inductance element.

According to another aspect of the present disclosure, a method for fabricating a semiconductor device includes steps as follows. A first wafer including a first substrate and a first inductance layer is provided. The first inductance layer includes a first metal line and a first interconnect structure. The first metal line is disposed on the first substrate, and the first interconnect structure is electrically connected with the first metal line. A second wafer including a second substrate and a second inductance layer is provided. The second inductance layer includes a second metal line and a second interconnect structure. The second metal line is disposed on the second substrate, and the second interconnect structure is electrically connected with the second metal line. The second interconnect structure is bonded with the first interconnect structure, so that the first inductance layer and the second inductance layer together form an inductance element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic cross-sectional views showing steps of a method for fabricating a semiconductor device according to an embodiment of the present disclosure.

FIG. 3 is a schematic top view showing an inductance element according to an embodiment of the present disclosure.

FIG. 4 is an exploded diagram of the inductance element shown in FIG. 3.

FIG. 5 is a three-dimensional diagram of the inductance element shown in FIG. 3.

FIG. 6 is a schematic top view showing an inductance element according to another embodiment of the present disclosure.

FIG. 7 is a schematic top view showing a first metal line and a second metal line adjacent to each other of the inductance element shown in FIG. 6.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

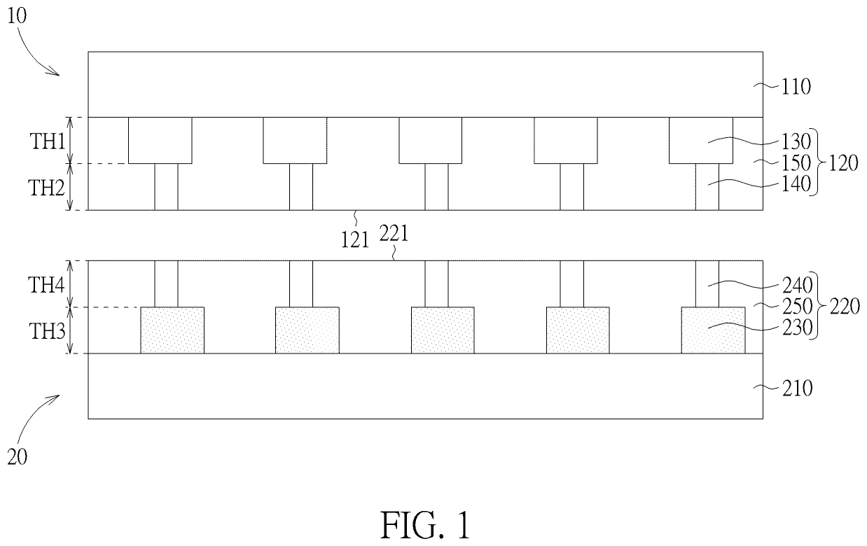

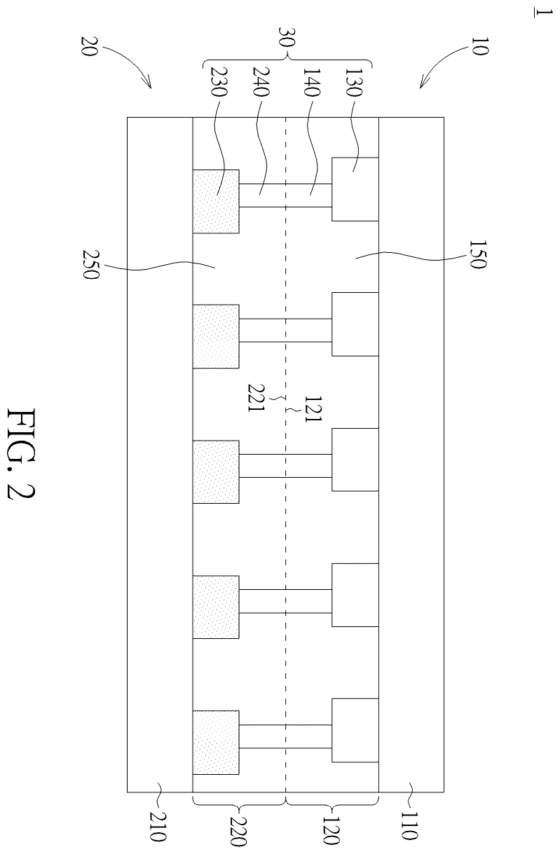

Please refer to FIG. 1 to FIG. 2, which are schematic cross-sectional views showing steps of a method for fabricating a semiconductor device 1 according to an embodiment of the present disclosure. In FIG. 1, a first wafer 10 and a second wafer 20 are provided. The first wafer 10 includes a first substrate 110 and a first inductance layer 120. The first inductance layer 120 includes a first metal line 130 and a first interconnect structure 140. The first metal line 130 is disposed on the first substrate 110, and the first interconnect structure 140 is electrically connected with the first metal line 130. The second wafer 20 includes a second substrate 210 and a second inductance layer 220. The second inductance layer 220 includes a second metal line 230 and a second interconnect structure 240. The second metal line 230 is disposed on the second substrate 210, and the second interconnect structure 240 is electrically connected with the second metal line 230.

For example, the first wafer 10 may be fabricated as follows. First, the first substrate 110 may be provided. The first substrate 110, for example, may be a silicon substrate, an epitaxial silicon substrate, a silicon carbide substrate or a silicon on insulator (SOI) substrate. The first substrate 110 may be formed with active elements (not shown) or passive elements (not shown), such as transistors, diodes, capacitors, inductance elements or resistors, according to actual needs. Moreover, the first substrate 110 may be formed with a metal interconnection structure (not shown) according to actual needs, and the metal interconnection structure may also include other circuit elements, such as capacitors, inductance elements, resistors and embedded memories.

Next, a first inductance layer 120 may be formed on the first substrate 110. For example, a dielectric material may be formed on the first substrate 110, and then one or more lithography and etching processes may be performed to remove a portion of the dielectric material to form holes (not labeled). Next, a conductive material is filled into each of the holes and a planarization process such as a chemical mechanical polishing (CMP) process is performed to form the first metal line 130. Next, the above processes may be repeated to form the first interconnect structure 140. The remaining dielectric material forms the first dielectric layer 150, so as to complete the back-end-of-the-line (BEOL) process. In other words, the first inductance layer 120 is the topmost metal layer of the first wafer 10. That is, the first inductance layer 120 is the metal layer of the first wafer 10 that is farthest from the first substrate 110.

As shown in FIG. 1, the first inductance layer 120 further includes the first dielectric layer 150. The first dielectric layer 150 covers the first metal line 130. The first interconnect structure 140 is embedded in the first dielectric layer 150. An end of the first interconnect structure 140 is electrically connected with the first metal line 130, and another end of the first interconnect structure 140 exposes from the first dielectric layer 150. In some embodiments, the first interconnect structure 140 and the first metal line 130 may be integrally formed. A side of the first inductance layer 120 away from the first substrate 110 has a first bonding surface 121. According to an embodiment of the present disclosure, the thickness TH1 of the first metal line 130 may range from 16750 Å to 50250 Å, and the thickness TH2 of the first interconnection structure 140 may range from 5000 Å to 15000 Å.

For example, the second wafer 20 may be fabricated as follows. First, the second substrate 210 may be provided. The second substrate 210, for example, may be a silicon substrate, an epitaxial silicon substrate, a silicon carbide substrate or a silicon on insulator (SOI) substrate. The second substrate 210 may be formed with active elements (not shown) or passive elements (not shown), such as transistors, diodes, capacitors, inductance elements or resistors, according to actual needs. Moreover, the second substrate 210 may be formed with a metal interconnection structure (not shown) according to actual needs, and the metal interconnection structure may also include other circuit elements, such as capacitors, inductance elements, resistors and embedded memories.

Next, a second inductance layer 220 may be formed on the second substrate 210. For example, a dielectric material may be formed on the second substrate 210, and then one or more lithography and etching processes may be performed to remove a portion of the dielectric material to form holes (not labeled). Next, a conductive material is filled into each of the holes and a planarization process such as a CMP process is performed to form the second metal line 230. Next, the above processes may be repeated to form the second interconnect structure 240. The remaining dielectric material forms the second dielectric layer 250, so as to complete the BEOL process. In other words, the second inductance layer 220 is the topmost metal layer of the second wafer 20. That is, the second inductance layer 220 is the metal layer of the second wafer 20 that is farthest from the second substrate 210.

As shown in FIG. 1, the second inductance layer 220 further includes the second dielectric layer 250. The second dielectric layer 250 covers the second metal line 230. The second interconnect structure 240 is embedded in the second dielectric layer 250. An end of the second interconnect structure 240 is electrically connected with the second metal line 230, and another end of the second interconnect structure 240 exposes from the second dielectric layer 250. In some embodiments, the second interconnect structure 240 and the second metal line 230 may be integrally formed. A side of the second inductance layer 220 away from the second substrate 210 has a second bonding surface 221. According to an embodiment of the present disclosure, the thickness TH3 of the second metal line 230 may range from 16750 Å to 50250 Å, and the thickness TH4 of the second interconnection structure 240 may range from 5000 Å to 15000 Å.

The materials of the first dielectric layer 150 and the second dielectric layer 250 may independently include silicon dioxide (SiO₂), silicon nitride (SiN), silicon oxynitride (SiON), silicon carbonitride (SiCN), nitrogen-doped silicon carbide (NDC), low dielectric constant (low-k) dielectric material, such as fluorinated silica glass (FSG), carbon doped silicon oxide (SiCOH), spin-on glass, porous low-k dielectric material, organic polymer dielectric material, plasma enhanced oxide, or other suitable dielectric materials. The conductive materials forming the first metal line 130, the first interconnection structure 140, the second metal line 230 and the second interconnection structure 240 may include a barrier layer (not shown) and a metal layer (not shown). The material of the barrier layer may include titanium (Ti), tantalum (Ta), titanium nitride (TiN), tantalum nitride (TaN) or a combination thereof. The material of the metal layer may include aluminum (Al), titanium (Ti), tantalum (Ta), tungsten (W), niobium (Nb), molybdenum (Mo), copper (Cu) or a combination thereof, but not limited thereto. The conductive materials forming the first metal line 130, the first interconnection structure 140, the second metal line 230 and the second interconnection structure 240 may only include the metal layer.

As shown in FIG. 2, the second interconnect structure 240 is bonded with the first interconnect structure 140, so that the first inductance layer 120 and the second inductance layer 220 together form an inductance element 30. Thereby, the fabrication of the semiconductor device 1 can be completed. The inductance element 30 includes the first metal line 130, the first interconnect structure 140, the second metal line 230 and the second interconnect structure 240. For example, the first wafer 10 and the second wafer 20 may be subjected to a face-to-face bonding process, such as a hybrid bonding process, so that the first bonding surface 121 of the first inductance layer 120 is bonded with the second bonding surface 221 of the second inductance layer 220. Furthermore, the aforementioned active elements and/or passive elements of the first substrate 110 of the first wafer 10 and the aforementioned active elements and/or passive elements of the second substrate 210 of the second wafer 20 may be connected through other interconnect structure, such as the hybrid bonding and through silicon vias (TSVs), so as to achieve 2.5-dimensional (2.5D) packaging or 3-dimensional (3D) packaging.

In some embodiments, the first wafer 10 and the second wafer 20 may be planarized first when the hybrid bonding process is performed, and then the planarized first bonding surface 121 of the first wafer 10 and the planarized second bonding surface 221 of the second wafer 20 are arranged face-to-face and aligned. Specifically, the first interconnect structure 140 is aligned and contacts the second interconnect structure 240, and the first dielectric layer 150 is aligned and contacts the second dielectric layer 250, so that the first bonding surface 121 and the second bonding surface 221 may be pre-bonded by Van der Waals force. In some embodiments, an activation process and a heat treatment process may be performed on the first bonding surface 121 and the second bonding surface 221. The activation process can be, for example, a plasma treatment. With the activation process, it is beneficial to reduce the contact pressure and temperature required in the subsequent heat treatment process. The bonding between the first bonding surface 121 and the second bonding surface 221 can be strengthened through the heat treatment process. For example, the first bonding surface 121 and the second bonding surface 221 can be annealed at a temperature of about 200° C. to 400° C. for a period of about 1 hour to 2 hours. During the annealing, the metals in the first interconnect structure 140 and the second interconnect structure 240 contact and then diffuse each other due to thermal expansion to form a metal-to-metal bonding. The corresponding first dielectric layer 150 and the second dielectric layer 250 may also be bonded to each other at the temperature.

According to above description, the inductance element 30 according to the present disclosure formed by the topmost metal layer of the first wafer 10 and the topmost metal layer of the second wafer 20. In general, the topmost metal layer of a wafer may be arranged with a thicker thickness, which is beneficial to enhance the quality factor (Q factor) of an inductance element and is beneficial to provide a larger inductance value with fewer metal layers. As for a stacked spiral inductance element formed in a single wafer, it requires more metal layers. As for a two-dimensional spiral inductance element formed in a single wafer, it requires a larger area. In comparison, the inductance element 30 according to the present disclosure is advantageous in maintaining or improving the quality factor and the inductance value while reducing the volume and/or the area thereof. In addition, the topmost metal layer of the first wafer 10 and the topmost metal layer of the second wafer 20 are respectively far away from the first substrate 110 and the second substrate 210, which is beneficial to reduce the parasitic resistance and the parasitic capacitance.

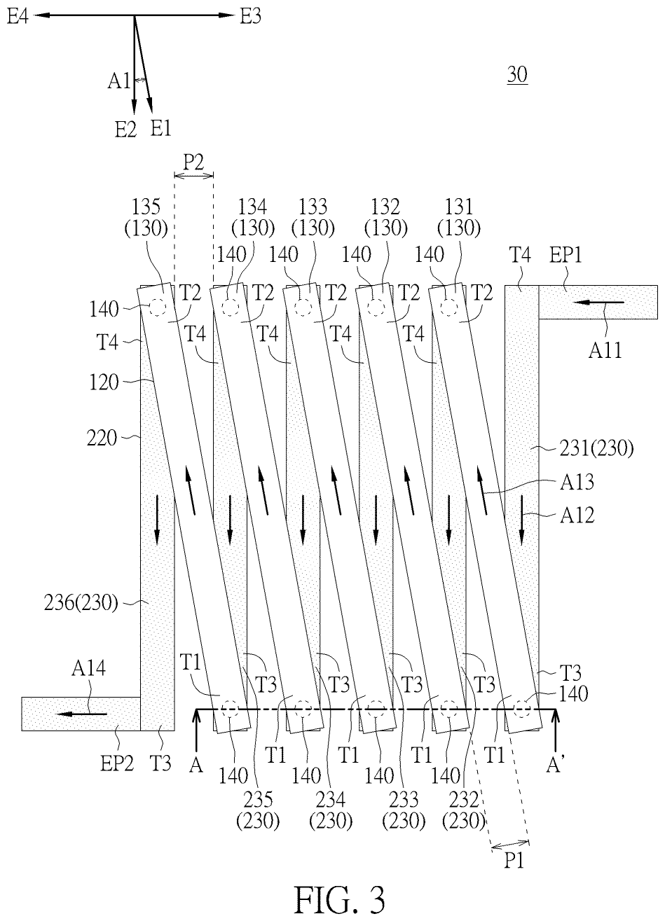

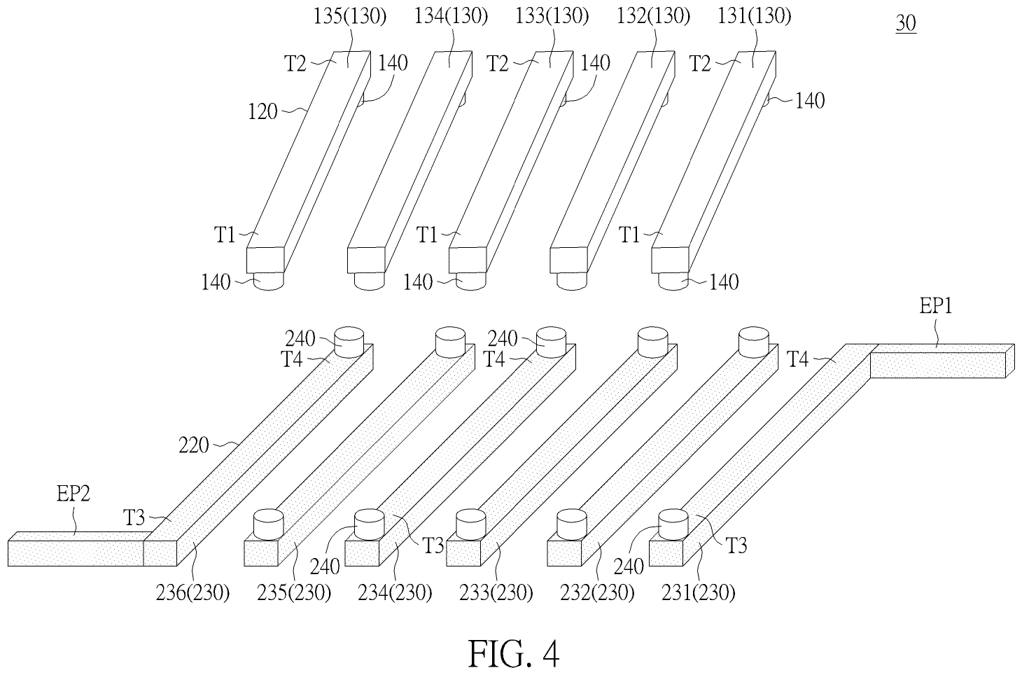

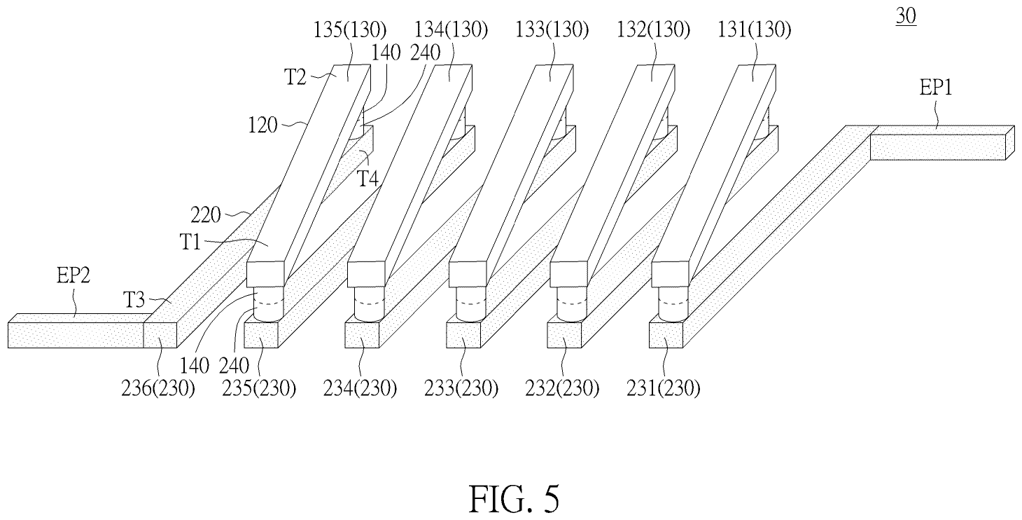

Please refer to FIG. 3 to FIG. 5. FIG. 3 is a schematic top view showing an inductance element 30 according to an embodiment of the present disclosure. The viewing angle of FIG. 2 may be taken along line A-A′ shown in FIG. 3. FIG. 4 is an exploded diagram of the inductance element 30 shown in FIG. 3, which corresponds the state shown in FIG. 1. FIG. 5 is a three-dimensional diagram of the inductance element 30 shown in FIG. 3, which corresponds the state shown in FIG. 2. As shown in FIG. 3 to FIG. 5, the first inductance layer 120 may include a plurality of the first metal lines 130. For convenience of explanation, the number of the first metal lines 130 is exemplary five. The first metal lines 130 are, from left to right, the first metal lines 131, 132, 133, 134 and 135. However, it is only exemplary, and the number of the first metal lines 130 may be adjusted according to actual needs. Each of the first metal lines 130 has a first extending direction E1, each of the first metal lines 130 fixedly extends along the first extending direction E1, and the plurality of the first metal lines 130 are parallel to each other. In the present disclosure, when an element has an extending direction, it may refer that the element extends along the extending direction, and the element has a maximum length in the extending direction.

In the top view of the inductance element 30, the first metal line 130 may include a strip shape, such as a rectangular shape, but not limited thereto. In other embodiments, the strip shape may be other elongated shapes, such as an elongated ellipse or an elongated trapezoid. Each of the first metal lines 130 includes a first end T1 and a second end T2 opposite to each other. The first end T1 and the second end T2 of each of the first metal lines 130 are respectively disposed with a first interconnect structure 140, but not limited thereto. The number of first interconnect structures 140 disposed on the first end T1 and the second end T2 may be adjusted according to actual needs, and the number of the first interconnect structures 140 disposed on the first end T1 may be identical to or different from the number of the first interconnect structures 140 disposed on the second end T2.

The second inductance layer 220 may include a plurality of the second metal lines 230. For convenience of explanation, the number of the second metal lines 230 is exemplary six, and the second metal lines 230 are the second metal lines 231, 232, 233, 234, 235 and 236. Each of the second metal lines 230 has a second extending direction E2, each of the second metal line 230 fixedly extends along the second extending direction E2, and the plurality of second metal lines 230 are parallel to each other. In the top view of the inductance element 30, the second metal line 230 may include a strip shape, such as a rectangular shape, but not limited thereto. The first end T3 and the second end T4 of each of the second metal lines 230 are respectively disposed with a second interconnect structure 240, but not limited thereto. The number of the second interconnect structures 240 disposed on the first end T3 and the second end T4 may be adjusted according to the number of the first interconnect structures 140.

The second extending direction E2 is oblique relative to the first extending direction E1. In the present disclosure, when one direction/element is oblique relative to another direction/element, it may refer that the direction/element and the another direction/element are not parallel to each other and not perpendicular to each other. For example, the smaller included angle between the direction/element and the other direction/element is less than 90 degrees. As shown in FIG. 3, the included angle A1 between the first extending direction E1 and the second extending direction E2 is less than 90 degrees. In other words, the first metal line 130 is oblique relative to the second metal line 230, the first metal line 130 is not parallel to the second metal line 230, and the first metal line 130 is not perpendicular to the second metal line 230. Thereby, it is beneficial to arrange the inductance element 30 into different geometric shapes, which is beneficial to flexibly adjust the magnetic field direction of the inductance element 30.

The inductance element 30 may further include a first extending segment EP1 and a second extending segment EP2. One of the first extending segment EP1 and the second extending segment EP2 may serve as an input terminal for the current (not shown), and the other of the first extending segment EP1 and the second extending segment EP2 may serve as an output terminal for the current. For example, when the first extending segment EP1 serves as the input terminal for the current and the second extending segment EP2 serves as the output terminal of the current, the current may flow from the first extending segment EP1 to the second end T4 of the second metal line 231 along the direction of the arrow A11, then flows from the second end T4 of the second metal line 231 to the first end T3 along the direction of the arrow A12, then flows upward through the second interconnect structure 240 and the first interconnect structure 140 to the first end T1 of the first metal line 131, then flows from the first end T1 of the first metal line 131 to the second end T2 along the direction of the arrow A13, then flows downward through the first interconnect structure 140 and the second interconnect structure 240 to the second end T4 of the second metal line 232, and so on. As last, the current flows out from the second extending segment EP2 along the direction of the arrow A14. When the first extending segment EP1 serves as the output terminal for the current and the second extending segment EP2 serves as the input terminal for the current, the flow directions of the current are opposite to that mentioned above.

In this embodiment, the first extending segment EP1 and the second extending segment EP2 are disposed in the second inductance layer 220, and are respectively connected to the outermost second metal lines 231 and 236 of the second inductance layer 220, but not limited thereto. In other embodiments, both the first extending segment EP1 and the second extending segment EP2 may be disposed in the first inductance layer 120. Alternatively, one of the first extending segment EP1 and the second extending segment EP2 may be disposed in the first inductance layer 120, and the other one of the first extending segment EP1 and the second extending segment EP2 may be disposed in the second inductance layer 220. For example, in other embodiments, the second metal line 231, the second interconnect structure 240 and the first interconnect structure 140 located on the first end T3 of the second metal line 231 may be omitted, and the first extending segment EP1 is connected with the first end T1 of the first metal line 131. As another example, in other embodiments, the second metal line 236, the second interconnect structure 240 and the first interconnect structure 140 located on the second end T4 of the second metal line 236 can be further omitted, and the second extending segment EP2 is connected with the second end T2 of the first metal line 135. In other words, the positions of the first extending segment EP1 and the second extending segment EP2 may be adjusted according to actual needs. The first extending segment EP1 may have a third extending direction E3, and the second extending segment EP2 may have a fourth extending direction E4. Herein, the third extending direction E3 is different from the first extending direction E1 and the second extending direction E2, the fourth extending direction E4 is different from the first extending direction E1 and the second extending direction E2, the fourth extending direction E4 may be parallel to the third extending direction E3, and the third extending direction E3 and the fourth extending direction E4 may be perpendicular to the second extending direction E2, but not limited thereto. The third extending direction E3 and the fourth extending direction E4 may be adjusted according to actual needs.

As shown in FIG. 3, in the top view of the inductance element 30, the first end T1 of the first metal line 130 overlaps the first end T3 of the second metal line 230, and the second end T2 of the same first metal line 130 is misaligned with the second end T4 of the same second metal line 230. In the top view of the inductance element 30, the plurality of the first metal lines 130 and the plurality of the second metal lines 230 are arranged to form a zigzag pattern.

Specifically, in the top view of the inductance element 30, the first end T1 of the first metal line 131 and the first end T3 of the second metal line 231 overlap with each other and are electrically connected with each other through the first interconnect structure 140 and the second interconnect structure 240 (i.e., the first end T1 of the first metal line 131, the first interconnect structure 140, the second interconnect structure 240 and the first end T3 of the second metal line 231 overlap with each other), and the second end T2 of the first metal line 131 is misaligned with the second end T4 of the second metal line 231. The second end T2 of the first metal line 131 and the second end T4 of the second metal line 232 overlap each other and are electrically connected with each other through the first interconnect structure 140 and the second interconnect structure 240 (i.e., the second end T2 of the first metal line 131, the first interconnect structure 140, the second interconnect structure 240 and the second end T4 of the second metal line 232 overlap with each other), and the first end T1 of the first metal line 131 is misaligned with the first end T3 of the second metal line 232. The first end T1 of the first metal line 132 overlaps the first end T3 of the second metal line 232, and the second end T2 of the first metal line 132 is misaligned with the second end T4 of the second metal line 232. The second end T2 of the first metal line 132 overlaps the second end T4 of the second metal line 233, and the first end T1 of the first metal line 132 is misaligned with the first end T3 of the second metal line 233, and so on. In other words, among any two adjacent first metal line 130 and second metal line 230, only one ends of the two adjacent first metal line 130 and second metal line 230 overlap with each other and the other ends of the two adjacent first metal line 130 and second metal line 230 are misaligned with each other. Furthermore, except the metal lines (herein, the second metal lines 231 and 236) directly connected with the first extending segment EP1 and the second extending segment EP2, two ends of the first metal line 130 (such as the first metal lines 131, 132, 133, 134 and 135) may respectively overlap two ends of two adjacent second metal lines 230, and two ends of the second metal line (such as the second metal lines 232, 233, 234 and 235) may respectively overlap with two adjacent first metal lines 130. With one end of the first metal line 130 overlapping one end of the second metal line 230, it is beneficial to reduce the spaced distance P1 between two adjacent first metal lines 130 and/or the spaced distance P2 between two adjacent second metal lines 230, which is beneficial to reduce the entire area of the inductance element 30.

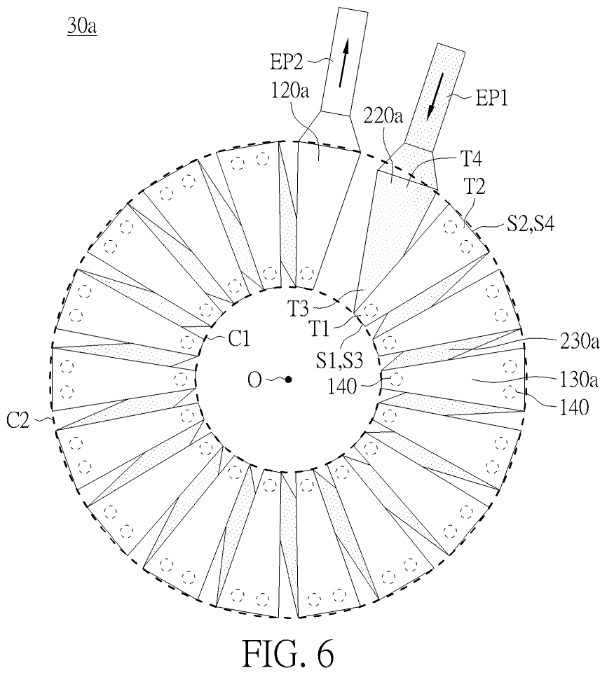

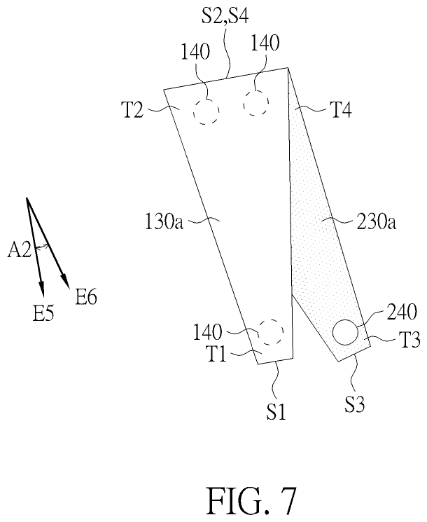

Please refer to FIG. 6 to FIG. 7. FIG. 6 is a schematic top view showing an inductance element 30a according to another embodiment of the present disclosure. FIG. 7 is a schematic top view showing a first metal line 130a and a second metal line 230a adjacent to each other of the inductance element 30a shown in FIG. 6. As shown in FIG. 6 and FIG. 7, the first inductance layer 120a may include a plurality of first metal lines 130a. The plurality of first metal lines 130a are arranged to form a radial pattern, and the plurality of first metal lines 130a are arranged to form an annular shape. In the top view of the inductance element 30a, the first metal line 130a includes a fan shape or a trapezoidal shape. The second inductance layer 220a may include a plurality of second metal lines 230a. The plurality of second metal lines 230a are arranged to form a radial pattern, and the plurality of second metal lines 230a are arranged to form an annular shape. In the top view of the inductance element 30a, the second metal line 230a includes a fan shape or a trapezoidal shape.

Each of the first metal lines 130a has a first extending direction, such as the first extending direction E5 shown in FIG. 7, and each of the first metal lines 130a fixedly extends along the first extending direction. Herein, the first extending directions of the plurality of first metal lines 130a may be different from each other. In some embodiments, the inner edges S1 of the plurality of first metal lines 130a are located at a circumference of a first virtual circle C1, and the outer edges S2 of the plurality of first metal lines 130a are located at a circumference of a second virtual circle C2. The first virtual circle C1 and the second virtual circle C2 may be disposed concentrically and have the same circle center O, and the first extending direction of each of the first metal lines 130a may pass through the circle center O along the radial direction. The aforementioned the inner edges S1 of the first metal lines 130a located at the circumference of the first virtual circle C1 may refer that at least a portion of each of the inner edges S1, such as two ends of each of the inner edges S1, is located at the circumference of the first virtual circle C1. The aforementioned the outer edges S2 of the first metal lines 130a located at the circumference of the second virtual circle C2 may refer that at least a portion of each of the outer edges S2, such as two ends of each of the outer edges S2, is located at the circumference of the second virtual circle C2.

Each of the second metal line 230a has a second extending direction, such as the second extending direction E6 shown in FIG. 7, and each of the second metal line 230a fixedly extends along the second extending direction. Herein, the second extending directions of the plurality of second metal lines 230a may be different from each other. In some embodiments, the inner edges S3 of the plurality of second metal lines 230a are located at the circumference of the first virtual circle C1, and the outer edges S4 of the plurality of second metal lines 230a are located at the circumference of the second virtual circle C2. The second extending direction of each of the second metal lines 230a deviates from the radial direction and does not pass through the circle center O. The aforementioned the inner edges S3 of the second metal lines 230a located at the circumference of the first virtual circle C1 may refer that at least a portion of each of the inner edges S3 is located at the circumference of the first virtual circle C1. The aforementioned the outer edges S4 of the second metal lines 230a located at the circumference of the second virtual circle C2 may refer that at least a portion of each of the outer edges S4 is located at the circumference of the second virtual circle C2.

In some embodiments, each of the first metal line 130a and the second metal line 230a include a trapezoidal shape, the first virtual circle C1 and the second virtual circle C2 may be disposed concentrically about the circle center O, the upper side (i.e., the inner edge S1) of each of the first metal line 130a overlaps the upper side (i.e., the inner edge S3) of a second metal line 230a, and the lower side (i.e., the outer edge S2) of each of the first metal line 130a overlaps the lower side (i.e., the outer edge S4) of a second metal line 230a. In the present disclosure, two elements overlapping with each other may refer that the two elements partially overlap or completely overlap with each other along one direction.

Among any two adjacent first metal line 130a and second metal line 230a, the second extending direction of the second metal line 230a is oblique relative to the first extending direction of the first metal line 130a, and an included angle between the second extending direction of the second metal line 230a and the first extending direction of the first metal line 130a is less than 90 degrees. For example, the included angle A2 between the first extending direction E5 and the second extending direction E6 shown in FIG. 7 is less than 90 degrees. In other words, among any two adjacent first metal line 130a and second metal line 230a, the first metal line 130a is oblique relative to the second metal line 230a, the first metal line 130a is not parallel to the second metal line 230a, and the first metal line 130a is not perpendicular to the second metal line 230a. Thereby, it is beneficial to flexibly adjust the magnetic field direction of the inductance element 30a.

The inductance element 30a may further include a first extending segment EP1 and a second extending segment EP2. One of the first extending segment EP1 and the second extending segment EP2 may serve as an input terminal for the current, and the other one of the first extending segment EP1 and the second extending segment EP2 may serve as an output terminal for the current. For details about the first extending segment EP1, the second extending segment EP2 and the flow direction of the current, references may be made to the above description and are omitted herein.

As shown in FIG. 6, each of the first metal lines 130a includes a first end T1 and a second end T2 opposite to each other. The first interconnect structures 140 may be disposed on the first end T1 and the second end T2 of the first metal line 130a, and the number of first interconnect structures 140 on the first end T1 may be different from the number of first interconnect structures 140 on the second end T2. Each of the second metal lines 230a includes a first end T3 and a second end T4 opposite to each other. The second interconnect structures 240 may be disposed on the first end T3 and the second end T4 of the second metal line 230a, and the number of the second interconnect structures 240 on the first end T3 may be different from the number of the second interconnect structures 240 on the second end T4. Herein, the number of the first interconnect structure 140 disposed on the first end T1 is one, and the number of the second interconnect structure 240 disposed on the first end T3 is one. The number of the first interconnect structures 140 disposed on the second end T2 is two, and the number of the second interconnect structures 240 disposed on the second end T4 is two. However, it is only exemplary, and the number of the first interconnect structures 140 and the number of the second interconnect structure 240 disposed on each end may be adjusted according to actual needs. In the top view of the inductance element 30a, the first end T1 of the first metal line 130a overlaps the first end T3 of the second metal line 230a, and the first end T1 of the first metal line 130a and the first end T3 of the second metal line 230a are electrically connected through the first interconnect structure 140 and the second interconnect structure 240 (i.e., the first end T1 of the first metal line 130a, the first interconnect structure 140, the second interconnect structure 240 and the first end T3 of the second metal line 230a overlap with each other), and the second end T2 of the same first metal line 130a is misaligned with the second end T4 of the same second metal line 230a.

In other words, among any two adjacent first metal line 130a and second metal line 230a, only one ends of the two adjacent first metal line 130a and second metal line 230a overlap with each other and the other ends the two adjacent first metal line 130a and second metal line 230a are misaligned with each other. Furthermore, except the metal lines directly connected with the first extending segment EP1 and the second extending segment EP2, two ends of the first metal line 130a may respectively overlap two adjacent second metal lines 230a, and two ends of the second metal line 230a may respectively overlap two adjacent first metal lines 130a. With one end of the first metal line 130a overlapping one end of the second metal line 230a, it is beneficial to reduce the spaced distance (not labeled) between two adjacent first metal lines 130a and/or the spaced distance (not labeled) between two adjacent second metal lines 230a, which is beneficial to reduce the entire area of the inductance element 30a. For other details about the inductance element 30a, references may be made to the above description and are not repeated herein.

Compared with the prior art, the semiconductor device according to the present disclosure uses the topmost metal layers of the two wafers to form the inductance element, which is beneficial to maintain or improve the quality factor and inductance value of the inductance element while reducing the volume and/or the area of the inductance element. It is beneficial to reduce the parasitic resistance and the parasitic capacitance, so as to improve the properties of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a first wafer, comprising:
a first substrate; and
a first inductance layer, comprising a first metal line and a first interconnect structure, wherein the first metal line is disposed on the first substrate, and the first interconnect structure is electrically connected with the first metal line; and
a second wafer, comprising:
a second substrate; and
a second inductance layer, comprising a second metal line and a second interconnect structure, wherein the second metal line is disposed on the second substrate, the second interconnect structure is electrically connected with the second metal line, and the second interconnect structure is bonded with the first interconnect structure, so that the first inductance layer and the second inductance layer together form an inductance element.

2. The semiconductor device of claim 1, wherein the first metal line has a first extending direction, the second metal line has a second extending direction, and the second extending direction is oblique relative to the first extending direction.

3. The semiconductor device of claim 2, wherein the first metal line fixedly extends along the first extending direction.

4. The semiconductor device of claim 1, wherein in a top view of the inductance element, an end of the first metal line overlaps an end of the second metal line, and another end of the first metal line is misaligned with another end of the second metal line.

5. The semiconductor device of claim 1, wherein there are a plurality of the first metal lines, there are a plurality of the second metal lines, and the plurality of the first metal lines and the plurality of the second metal lines are arranged to form a zigzag pattern.

6. The semiconductor device of claim 1, wherein there are a plurality of the first metal lines, and the plurality of the first metal lines are parallel with each other.

7. The semiconductor device of claim 6, wherein there are a plurality of the second metal lines, the plurality of the second metal lines are parallel with each other, and the plurality of the first metal lines are not parallel to the plurality of the second metal lines.

8. The semiconductor device of claim 1, wherein there are a plurality of the first metal lines, and the plurality of the first metal lines are arranged to form a radial pattern.

9. The semiconductor device of claim 1, wherein there are a plurality of the first metal lines, and the plurality of the first metal lines are arranged to form an annular shape.

10. The semiconductor device of claim 1, wherein in a top view of the inductance element, and first metal line has a strip shape or a fan shape.

11. A method for fabricating a semiconductor device, comprising:
providing a first wafer comprising a first substrate and a first inductance layer, wherein the first inductance layer comprises a first metal line and a first interconnect structure, the first metal line is disposed on the first substrate, and the first interconnect structure is electrically connected with the first metal line;
providing a second wafer comprising a second substrate and a second inductance layer, wherein the second inductance layer comprises a second metal line and a second interconnect structure, the second metal line is disposed on the second substrate, and the second interconnect structure is electrically connected with the second metal line; and
bonding the second interconnect structure with the first interconnect structure, so that the first inductance layer and the second inductance layer together form an inductance element.

12. The method of claim 11, wherein the first metal line has a first extending direction, the second metal line has a second extending direction, and the second extending direction is oblique relative to the first extending direction.

13. The method of claim 12, wherein the first metal line fixedly extends along the first extending direction.

14. The method of claim 11, wherein in a top view of the inductance element, an end of the first metal line overlaps an end of the second metal line, and another end of the first metal line is misaligned with another end of the second metal line.

15. The method of claim 11, wherein there are a plurality of the first metal lines, there are a plurality of the second metal lines, and the plurality of the first metal lines and the plurality of the second metal lines are arranged to form a zigzag pattern.

16. The method of claim 11, wherein there are a plurality of the first metal lines, and the plurality of the first metal lines are parallel with each other.

17. The method of claim 16, wherein there are a plurality of the second metal lines, the plurality of the second metal lines are parallel with each other, and the plurality of the first metal lines are not parallel to the plurality of the second metal lines.

18. The method of claim 11, wherein there are a plurality of the first metal lines, and the plurality of the first metal lines are arranged to form a radial pattern.

19. The method of claim 11, wherein there are a plurality of the first metal lines, and the plurality of the first metal lines are arranged to form an annular shape.

20. The method of claim 11, wherein in a top view of the inductance element, and first metal line has a strip shape or a fan shape.
